(19) United States
(12) Patent Application Publication
(10) Pub. No.: US 2026/0255499 A1
(43) Pub. Date: Aug. 27, 2026

(54) ELEMENT TRANSFER DEVICE AND METHOD FOR CONTROLLING THE SAME

(71) Applicant: Chungang University Industry Academic Cooperation Foundation, Seoul (KR)

(72) Inventors: Jaesoo YOO, Seoul (KR); Yongtae KO, Gunpo-si (KR)

(73) Assignee: Chungang University Industry Academic Cooperation Foundation, Seoul (KR)

(21) Appl. No.: 19/545,313

(22) Filed: Feb. 20, 2026

(30) Foreign Application Priority Data
Feb. 24, 2025 (KR) 10-2025-0023697

(51) Int. Cl. H05K 3/303

(52) U.S. Cl. CPC H05K 3/303; H05K 2203/0147; H05K 2203/0292

(57) ABSTRACT

An element transfer device is provided. The element transfer device may include a polygonal container accommodating a substrate including element holes, vibration sources configured to generate vibrations and output the vibrations to a fluid within the container, a floating mask arranged on the substrate and including mask holes, and a processor configured to control an output of each of the vibration sources. The container may accommodate the floating mask, the fluid, and microelements distributed in the fluid. The processor may be further configured to perform a dispersion operation of controlling, in a state in which the floating mask is arranged on the substrate, the microelements to be dispersed in the fluid on the substrate through the mask holes in the floating mask, and a transfer operation of transferring, in a state in which the floating mask is removed from the container in which the substrate is arranged.

### CROSS-REFERENCE TO RELATED APPLICATION

This application is based on and claims priority under 35 U.S.C. § 119 to Korean Patent Application No. 10-2025-0023697, filed on Feb. 24, 2025, in the Korean Intellectual Property Office, the disclosure of which is incorporated by reference herein in its entirety.

### BACKGROUND

### 1. Field

The disclosure relates to an element transfer device for transferring a microelement onto a substrate by using a floating mask and a method for controlling the element transfer device. The disclosure may be applied to a large-scale transfer technique based on self-assembly of fine-scale functional semiconductor chips. In addition, such fine-scale chips may be widely applied across a broad range of fields from human biology to displays. In addition, the disclosure may be used to sort and collect such fine-scale chips at desired positions and arrange them in a desired pattern.

This research was supported by the Samsung Future Technology Development Program. (Project number: SRFC-IT2201-02)

### 2. Description of the Related Art

There is a growing demand for the development of technologies to artificially control the behavior of microelements in the display field and the semiconductor field of microstructures such as micro-electro mechanical systems (MEMS). In addition, in the biochemical field, there is a growing demand for the development of technologies capable of artificially controlling the behavior of particles at the level of multiple cells. Moreover, particles or elements used in these various fields are inevitably becoming increasingly miniaturized as technology advances.

To artificially control and manipulate such fine particles for their intended purposes, research and development have been conducted across various academic fields to date. For technologies for control and manipulation of fine particles, effects such as reduced power consumption, elemental non-destructive characteristics, and prevention of impurity contamination are required. For these reasons, technologies using acoustics, which require power as low as one hundred thousandth of that required when using optical techniques, have been studied.

Technologies using acoustics may move fine-scale elements, chips, etc., however, they are difficult to apply to environments in which a plurality of elements are moved on a large-sized substrate.

### SUMMARY

Additional aspects will be set forth in part in the description which follows and, in part, will be apparent from the description, or may be learned by practice of the presented embodiments of the disclosure.

According to an aspect of the disclosure, an element transfer device is provided. The element transfer device may include a polygonal container accommodating a substrate including a plurality of element holes, a plurality of vibration sources configured to generate vibrations and output the vibrations to a fluid within the container, a floating mask arranged on the substrate and including a plurality of mask holes, and a processor configured to control an output of each of the plurality of vibration sources. The container may accommodate the floating mask, the fluid, and microelements distributed in the fluid. The processor may be further configured to perform a dispersion operation of controlling, in a state in which the floating mask is arranged on the substrate, the microelements to be dispersed in the fluid on the substrate through the plurality of mask holes in the floating mask by outputting vibration from at least one of the plurality of vibration sources, and a transfer operation of transferring, in a state in which the floating mask is removed from the container in which the substrate is arranged, the microelements into the plurality of element holes in the substrate by outputting vibration from at least one of the plurality of vibration sources.

In addition, according to an embodiment, the element transfer device may further include a spacer attached to a bottom portion of the floating mask and preventing contact between the floating mask and the substrate. The floating mask may be arranged on the substrate such that the spacer is in contact with the substrate.

In addition, according to an embodiment, the plurality of vibration sources may include at least one vibration source of a first group, which is arranged on a circumference of a first circle having a radius of a first distance from a center point of the container, and at least one vibration source of a second group, which is arranged on a circumference of a second circle having a radius of a second distance greater than the first distance, the second circle being concentric with the first circle.

In addition, according to an embodiment, the at least one vibration source of the first group may be disposed on at least one short axis passing through the center point, and include at least one pair of vibration sources of the first group that facing each other with respect to the center point. The at least one vibration source of the second group may be disposed on at least one long axis passing through the center point, and include at least one pair of vibration sources of the second group that face each other with respect to the center point.

In addition, according to an embodiment, the container may have an octagonal shape. Each of the at least one short axis and the at least one long axis may be arranged to correspond to each corner of the octagonal container.

In addition, according to an embodiment, the processor may be further configured to, in the dispersion operation, control the floating mask to rotate by outputting a vibration wave from one of the plurality of vibration sources.

In addition, according to an embodiment, the processor may be further configured to, in the dispersion operation, reciprocally rotate the floating mask by outputting a vibration of a first frequency from a pair of vibration sources arranged on a first short axis among the at least one vibration source of the first group, and outputting a vibration of a second frequency different from the first frequency from a pair of vibration sources arranged on a second short axis among the at least one vibration source of the first group.

In addition, according to an embodiment, the processor may be configured to control a direction of the reciprocating rotation by adjusting a frequency and amplitude of the vibration output from the pair of vibration sources of the first group on the first short axis, and adjusting a frequency and amplitude of the vibration output from the pair of vibration sources of the first group on the second short axis.

In addition, according to an embodiment, the floating mask may include at least one of aluminum, stainless steel, Invar, or a high-rigidity organic material.

In addition, according to an embodiment, the floating mask may have a thickness of about 0.1 mm to about 1 mm.

In addition, according to an embodiment, the plurality of mask holes in the floating mask may have diameters of about 0.1 mm to about 0.3 mm and may be arranged in a two-dimensional array form with a pitch of about 0.1 mm to about 0.3 mm.

In addition, according to an embodiment, the substrate may correspond to a display panel included in a display module, the microelements may be light-emitting elements transferred onto the display panel, a pattern of the plurality of mask holes in the floating mask may correspond to a resolution of the display module, and sizes of the plurality of mask holes may be greater than sizes of each of the microelements by more than 0% and less than or equal to about 15%.

In addition, according to an embodiment, the processor may be further configured to obtain a first image of the substrate within the container in a state in which the floating mask is removed, and in the transfer operation, control, based on the first image, the plurality of vibration sources by using at least one of a plurality of transfer modes in which a predefined output frequency is output via at least one of the plurality of vibration sources.

In addition, according to an embodiment, the processor may be further configured to control the plurality of vibration sources to operate sequentially in two or more transfer modes among the plurality of transfer modes.

In addition, according to an embodiment, the processor may be further configured to determine, based on the first image, a transfer state of the microelements being transferred into the plurality of element holes in the substrate and positions of residual microelements that are not transferred onto the substrate, and control, based on the transfer state and the positions of the residual microelements, the plurality of vibration sources to operate in at least one transfer mode among the plurality of transfer modes.

In addition, according to an embodiment, the vibrations generated by the plurality of vibration sources may have frequencies of about 20 Hz to about 100 MHz.

In addition, according to an embodiment, the element transfer device may further include a plurality of connection plates respectively connecting the container and each of the plurality of vibration sources together.

In addition, according to an embodiment, the element transfer device may further include a camera configured to capture an image of the substrate within the container, wherein the processor may be further configured to determine, based on the image of the substrate captured by the camera, a transfer state of the microelements being transferred into the plurality of element holes in the substrate, and determine a transfer mode of the plurality of vibration sources based on the determined transfer state.

In addition, according to an embodiment, the fluid may include at least one of water, ethanol, acetone, isopropyl alcohol (IPA), ethylene glycol, dimethyl sulfoxide, glycerol, tetrahydrofuran, silicone oil, or nucleic acid.

According to another aspect of the disclosure, a method for controlling an element transfer device is provided. The method for controlling the element transfer device may include a dispersion operation of controlling, in a state in which a substrate including a plurality of element holes is arranged within a polygonal container storing a fluid and a floating mask is arranged on the substrate, microelements to be dispersed in the fluid on the substrate through a plurality of mask holes in the floating mask by outputting vibration from at least one of a plurality of vibration sources, and a transfer operation of transferring, in a state in which the floating mask is removed from the container in which the substrate is arranged, the microelements into the plurality of element holes in the substrate by outputting vibration from at least one of the plurality of vibration sources.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a structure of an element transfer device according to an embodiment;

FIG. 2 is a diagram illustrating structures of a floating mask and a substrate according to an embodiment;

FIG. 3 is a diagram illustrating a structure of an element transfer device according to an embodiment;

FIG. 4 is a flowchart illustrating a method for controlling an element transfer device, according to an embodiment;

FIG. 5 is a diagram illustrating a structure of a floating mask according to an embodiment;

FIG. 6 is a diagram illustrating a substrate, which is arranged within a container, and microelements, according to an embodiment;

FIG. 7 is a diagram illustrating a container and a plurality of vibration sources, according to an embodiment;

FIG. 8 is a diagram illustrating an arrangement of a plurality of vibration sources according to an embodiment;

FIG. 9 is a diagram illustrating an operation of a first dispersion mode according to an embodiment;

FIG. 10 is a diagram illustrating an operation of a second dispersion mode according to an embodiment;

FIG. 11 is a diagram illustrating an operation of a third dispersion mode according to an embodiment;

FIG. 12 is a diagram illustrating a structure of an element transfer device according to an embodiment;

FIG. 13 is a flowchart illustrating a transfer operation according to an embodiment;

FIG. 14 is a diagram illustrating definitions of a plurality of transfer modes according to an embodiment;

FIG. 15 is a diagram illustrating a plurality of transfer modes according to an embodiment;

FIG. 16 is a diagram illustrating a structure of a microelement according to an embodiment;

FIG. 17 is a diagram illustrating a result of a dispersion operation according to an embodiment and a result of a dispersion operation according to a comparative example; and

FIG. 18 is a diagram illustrating a result of a dispersion operation according to an embodiment and a result of a dispersion operation according to a comparative example.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The principles of the embodiments of the disclosure will be described and the embodiments will be disclosed to clarify the scope of the claims and to allow those of ordinary skill in the art to carry out the embodiments of the disclosure. The disclosed embodiments may be implemented in various forms.

Throughout the specification, the same elements are denoted by the same reference numerals. The disclosure does not describe all elements of the embodiments, and general matters in the technical field belonging to the embodiments of the disclosure or redundant matters between the embodiments will be omitted. The term ‘part’ (portion) used herein may be implemented as software or hardware, and depending on the embodiments, a plurality of ‘parts’ may be implemented as one unit (element), or a single ‘part’ may include a plurality of elements. Hereinafter, the embodiments of the disclosure and the operating principles of the embodiments will be described with reference to the attached drawings.

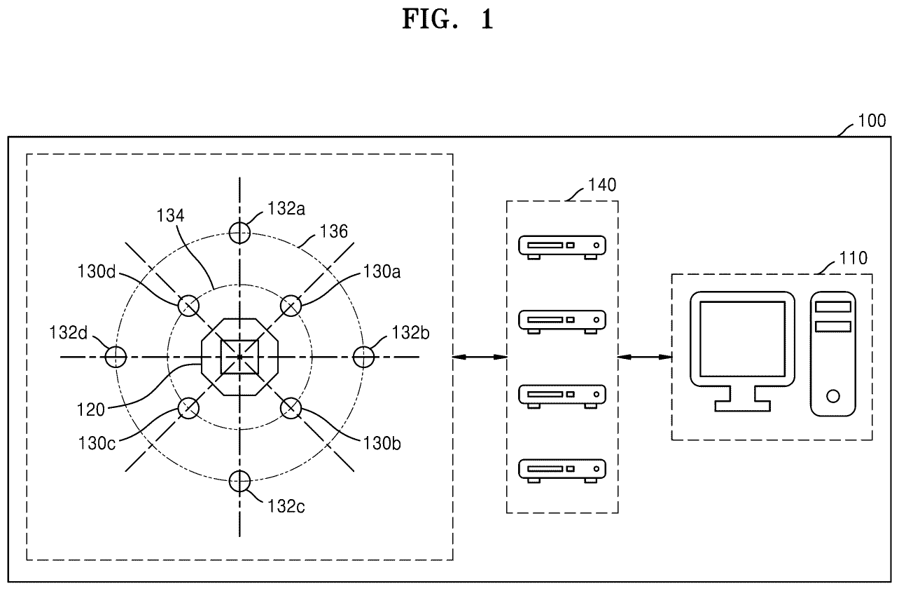

FIG. 1 is a diagram illustrating a structure of an element transfer device according to an embodiment.

An element transfer device 100 according to an embodiment includes a container 120 and a plurality of vibration sources 130a, 130b, 130c, 130d, 132a, 132b, 132c, and 132d. Throughout the specification, the plurality of vibration sources 130a, 130b, 130c, 130d, 132a, 132b, 132c, and 132d are collectively indicated by reference numeral 130.

The plurality of vibration sources 130 may be connected to the container 120 via a certain connection plate. The plurality of vibration sources 130 output vibrations of certain frequencies, and the vibrations output from the plurality of vibration sources 130 are transmitted to the container 120 via the connection plate.

The plurality of vibration sources 130 are controlled by a computing device 110 including a processor. The computing device 110 may output control signals to the plurality of vibration sources 130 to control at least one of on/off, an output frequency, a phase, a timing, or a vibration intensity of each of the plurality of vibration sources 130. The computing device 110 may determine output frequencies of the plurality of vibration sources 130 by using a certain computer program and data and may control the plurality of vibration sources 130 to output the determined output frequencies via the plurality of vibration sources 130.

The plurality of vibration sources 130 may generate and output vibrations based on signals output from a signal amplifier 140. The signal amplifier 140 may generate and output waveform signals corresponding to the output frequencies by using the control signals output from the computing device 110. The plurality of vibration sources 130 may generate and output vibrations corresponding to the output frequencies by receiving, from the signal amplifier 140, the waveform signals corresponding to the output frequencies.

The container 120 has a polygonal shape. The container 120 may have, for example, an octagonal shape. In addition, the container 120 may have, for example, a regular polygonal shape such as a regular octagonal shape.

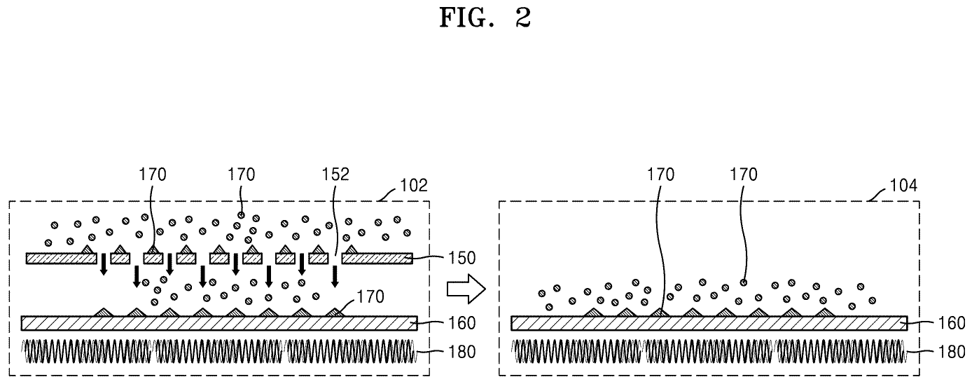

The container 120 has a fluid accommodation structure capable of accommodating a fluid. The fluid accommodation structure may be implemented in the form of a partition wall forming a space accommodating a fluid on an upper surface of the container 120. The fluid accommodation structure may correspond to, for example, a chunk. The fluid may correspond to, for example, ethanol. A substrate and a floating mask may be arranged within the container 120. The substrate and the floating mask may be arranged to be immersed in the fluid. The floating mask may be arranged on the substrate. The arrangement of the floating mask and the substrate will be described later with reference to FIG. 2.

According to an embodiment, the plurality of vibration sources 130 are arranged on a plurality of concentric circles 134 and 136. The number of the plurality of concentric circles 134 and 136 may be determined in various ways depending on an embodiment. According to an embodiment, the plurality of concentric circles 134 and 136 include the first circle 134 and the second circle 136. The first circle 134 has a smaller radius than the second circle 136. In addition, the plurality of vibration sources 130 may be arranged to respectively correspond to surfaces of the container 120 having a polygonal shape. For example, the container 120 has a regular octagonal shape, and eight vibration sources 130 may be arranged to respectively correspond to surfaces of the regular octagonal shape. The container 120 may be arranged at a center of the plurality of concentric circles 134 and 136.

The plurality of vibration sources 130 include: the vibration sources 130a, 130b, 130c, and 130d of a first group arranged on the first circle 134; and the vibration sources 132a, 132b, 132c, and 132d of a second group arranged on the second circle 136. The vibration sources 130a, 130b, 130c, and 130d of the first group include a plurality of vibration sources arranged on the first circle 134. The vibration sources 132a, 132b, 132c, and 132d of the second group include a plurality of vibration sources arranged on the second circle 136.

The computing device 110 controls an output of a vibration of a certain output frequency via one of the vibration sources 130a, 130b, 130c, and 130d of the first group and the vibration sources 132a, 132b, 132c, and 132d of the second group or a combination thereof. The computing device 110 may determine an output frequency of the vibration sources 130a, 130b, 130c, and 130d of the first group or the vibration sources 132a, 132b, 132c, and 132d of the second group in order to move microelements in a desired direction or pattern, and may output vibration of the determined output frequency via at least one vibration source among the vibration sources 130a, 130b, 130c, and 130d of the first group or at least one vibration source among the vibration sources 132a, 132b, 132c, and 132d of the second group.

As vibrations of at least one output frequency are output via the vibration sources 130a, 130b, 130c, and 130d of the first group and the vibration sources 132a, 132b, 132c, and 132d of the second group, the vibrations output from the plurality of vibration sources 130 are transmitted to the container 120 via the connection plate and are transmitted to the fluid within the container 120. As the vibrations are transmitted to the fluid, microelements in the fluid move in a certain direction or pattern due to the vibrations. The microelements are distributed along nodal lines of waves generated in the fluid by the vibrations. Throughout the specification, vibration is applied along each surface of the container 120 having a polygonal shape. Due to a combination of vibrations, the microelements may be dispersed in a desired pattern within the fluid. Therefore, the element transfer device 100 according to an embodiment may finely control movement of the microelements due to a combination of vibrations output via the plurality of vibration sources 130.

FIG. 2 is a diagram illustrating structures of a floating mask and a substrate according to an embodiment.

According to an embodiment, a floating mask 150 and a substrate 160 are arranged within the container 120. The floating mask 150 is arranged on the substrate 160. The floating mask 150 and the substrate 160 are arranged to be immersed in a fluid within the container 120. In addition, microelements 170 are arranged within the fluid. The microelements 170 may be randomly distributed within the fluid. The microelements 170 may be transferred into element holes in the substrate 160.

According to an embodiment, the floating mask 150 may be arranged to be in contact with a top surface of the substrate 160. In this case, when the floating mask 150 is arranged in contact with the substrate 160, the microelements 170 arranged on top of the floating mask 150 may have their movement controlled by an acoustic streaming force generated by applied waves, and thus may be arranged on the substrate 160 along the mask holes 152 in the floating mask 150. The microelements 170 are arranged on the substrate 160 along a pattern of the mask holes 152. According to an embodiment, in order to enhance accuracy in a bonding process for bonding the microelements 170 to the substrate 160, a pattern of the mask holes 152 on the floating mask 150 and a pattern of element holes on the substrate 160 may be formed to match each other. In addition, the floating mask 150 may be arranged in contact with the substrate 160 such that the pattern of the mask holes 152 on the floating mask 150 matches the pattern of the element holes on the substrate 160. When the substrate 160 corresponds to a display panel included in a display module and the microelements 170 correspond to light-emitting elements such as LEDs, the pattern and pitch of the mask holes 152 in the floating mask 150 may be configured to correspond to a resolution of a display module to be manufactured. In addition, the mask holes 152 are formed to have sizes up to about 15% greater than the sizes of the microelements 170, such that the microelements 170 may readily pass through the mask holes 152 and may be stably seated in the element holes in the substrate 160.

In addition, according to an embodiment, the floating mask 150 may be spaced apart from the substrate 160 by a spacer. In this case, due to a spacing formed between the floating mask 150 and the substrate 160, the top surface of the substrate 160 may not be in contact with the floating mask 150. The spacer may correspond to, for example, an O-ring. The floating mask 150 may rotate clockwise or counterclockwise or vibrate above the fixed substrate 160 due to an acoustic force generated by applied vibration. The floating mask 150 and the substrate 160 may vibrate or rotate together in the same motion pattern while each being in contact with the spacer.

The floating mask 150 may include the mask holes 152 through which elements may pass. The mask holes 152 may be arranged to cover the pattern of the element holes in the substrate 160. For example, the mask holes 152 may have the same arrangement size and shape as an area in which the element holes in the substrate 160 are arranged, or may have a larger arrangement size and shape than the area in which the element holes are arranged. The floating mask 150 may allow the microelements 170 to be dispersed such that the microelements 170 within the fluid are uniformly distributed on the substrate 160.

The substrate 160 includes the element holes for fixing the microelements 170. The element holes may be arranged in a certain pattern. For example, the element holes may be arranged in a two-dimensional array form. The pattern of the element holes may be determined to correspond to a pattern in which the microelements 170 are arranged on the substrate 160 to be manufactured.

The element holes may have shapes corresponding to the shapes of the microelements 170. In addition, each of the element holes may be formed to have a step relative to a top surface of the container 120 in order to accommodate the microelements 170, and may be formed as a recess. According to an embodiment, the microelements 170 may have asymmetric shapes. When the microelements 170 have asymmetric shapes, the element holes may also have asymmetric shapes corresponding to the microelements 170.

According to an embodiment, the element transfer device 100 may perform a dispersion operation 102 in a state in which the floating mask 150 is arranged on the substrate 160. The element transfer device 100 may disperse the microelements 170 within the fluid by outputting vibrations 180 from at least some of the plurality of vibration sources 130 while performing the dispersion operation 102. In addition, the element transfer device 100 may move the microelements 170 onto the substrate 160 via the mask holes 152 in the floating mask 150 by outputting the vibrations 180 from at least some of the plurality of vibration sources 130 while performing the dispersion operation 102. According to an embodiment, the element transfer device 100 may rotate or reciprocally rotate the floating mask 150 by outputting the vibrations 180 from at least some of the plurality of vibration sources 130. The microelements 170 may be uniformly distributed on the substrate 160 via the dispersion operation 102.

In addition, according to an embodiment, the element transfer device 100 may remove the floating mask 150 from the container 120 after the dispersion operation 102 ends. When the floating mask 150 is removed, the substrate 160 becomes visible on the top surface of the container 120. The element transfer device 100 performs a transfer operation 104 after the floating mask 150 is removed from the container 120. The transfer operation 104 is an operation of transferring the microelements 170 into the element holes in the substrate 160. While performing the transfer operation 104, the element transfer device 100 may output the vibrations 180 from the plurality of vibration sources 130. By the vibrations 180, the microelements 170 may be transferred into the element holes in the substrate 160. According to an embodiment, as the microelements 170 are uniformly distributed on the substrate 160 via the dispersion operation 102 using the floating mask 150, the element transfer device 100 may achieve a high transfer ratio in the transfer operation 104.

According to an embodiment, the element transfer device 100 may capture an image of the top surface of the substrate 160 by using a camera and may output vibrations from the plurality of vibration sources 130 based on the captured image. The element transfer device 100 may control behavior of the microelements 170 by outputting, based on the capture image, the vibrations 180 from the plurality of vibration sources 130 according to a certain transfer mode. The element transfer device 100 may output the vibrations 180 from the plurality of vibration sources 130 by setting, based on the captured image, a transfer mode to transfer the microelements 170 into empty element holes in the substrate 160. Operations of the plurality of vibration sources 130 according to a transfer mode will be described later.

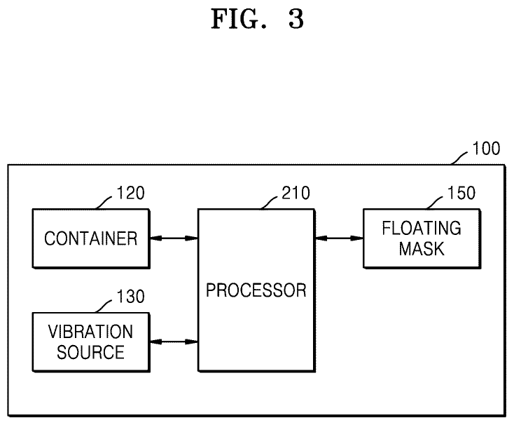

FIG. 3 is a diagram illustrating a structure of an element transfer device according to an embodiment.

According to an embodiment, the element transfer device 100 includes the container 120, a vibration source 130, the floating mask 150, and a processor 210. The container 120 is arranged to receive vibration output from the vibration source 130.

The container 120 may be connected to the vibration source 130 via a connection plate and may receive vibration output from the vibration source 130 via the connection plate. The container 120 may have a polygonal shape, for example, a regular octagonal shape, as described above. The container 120 accommodates the floating mask 150 and the substrate 160 and accommodates a fluid. In addition, the container 120 may accommodate the microelements 170 distributed within the fluid.

The fluid (or solvent) may be accommodated such that the floating mask 150 and the substrate 160 within the container 120 are immersed in the fluid. According to an embodiment, the fluid may include at least one of water, ethanol, or acetone. In addition, according to an embodiment, the fluid may include at least one or a mixture of at least some of isopropyl alcohol (IPA), ethylene glycol, dimethyl sulfoxide, glycerol, tetrahydrofuran, silicone oil, or nucleic acid. The fluid may be selected in consideration of interaction between the microelements 170 and the fluid, evaporation characteristics, etc.

In addition, the interaction between the microelements 170 and the fluid or the evaporation characteristics may be predicted or determined in consideration of surface tension, viscosity, contact angle, or the like.

The vibration source 130 is arranged around the container 120. The vibration source 130 includes a plurality of vibration sources. The plurality of vibration sources 130 are arranged on a plurality of concentric circles. The container 120 is arranged at a center of the concentric circles. The plurality of vibration sources 130 may include: the vibration sources 130a, 130b, 130c, and 130d of the first group arranged on the first circle 134; and the vibration sources 132a, 132b, 132c, and 132d of the second group arranged on the second circle 136. The second circle 136 has a greater radius than the first circle 134.

According to an embodiment, a difference in radius between the first circle 134 and the second circle 136 may be set to be about 3 cm to about 30 cm. When the difference in radius between the two concentric circles is less than 3 cm, it is difficult to induce a vortex caused by a difference in frequencies, that is, a beat frequency, during a process in which vibration from the vibration source 130 propagates and wave energy is transmitted to the container 120 containing the fluid. In addition, when the difference in radius between the two concentric circles is greater than or equal to 30 cm, it becomes difficult to drive the element transfer device 100 due to its structural design in terms of its overall weight and the durability of the vibration source 130. Therefore, according to an embodiment, by setting the difference in radius between the two concentric circles within a range of about 3 cm to about 30 cm, vibration transmission performance of the element transfer device 100 may be improved and durability may be enhanced.

The plurality of vibration sources 130 form waves in the fluid within the container 120. According to an embodiment, the plurality of vibration sources 130 may generate standing waves by outputting a vibration from a pair of vibration sources facing each other. Whether a standing wave is formed depends on an applied pulse signal and boundary conditions of a substrate under which a waveform is generated. A waveform generated in the fluid within the container 120 may vary depending on boundary conditions. This is related to an eigenvalue, and a standing wave is formed in the container 120 when a composite wave has the eigenvalue of a vibration signal. Vibrational energy applied to the microelements 170 as an external force is transmitted via shifts in the positions of nodal lines of vibration. In other words, the microelements 170 are brought together in a place where pressure decreases, and the plurality of vibration sources 130 induce movement of the microelements gathered in the place where the pressure decreases, via shifts in positions of nodal lines. The shifting of the nodal lines may be induced via generation of a composite wave by the plurality of vibration sources 130.

According to an embodiment, the plurality of vibration sources 130 may include at least one of an actuator, a lead zirconate titanate (PZT) transducer, or a speaker. The plurality of vibration sources 130 may generate and output standing waves having output frequencies.

According to an embodiment, the plurality of vibration sources 130 may output vibrations of output frequencies of about 10 Hz to about 100 MHz.

According to an embodiment, the plurality of vibration sources 130 may output vibrations of output frequencies of about 10 Hz to about 100 Hz. The vibrations of the output frequencies within the above range may correspond to acoustic waves. The acoustic waves may generate acoustic forces within the fluid due to the vibrations. According to an embodiment, a movement distance of the microelements 170 may be increased by outputting vibration of a long wavelength. In a case where the size of the element transfer device 100 increases, when the microelements 170 are moved by high-frequency vibration, a movement distance of the microelements 170 may be reduced and energy loss may occur.

According to an embodiment, the range of the output frequencies may vary depending on an application example. For example, the range of the output frequencies may be adjusted within a range of about 20 Hz to about 500 Hz according to the size of the substrate 160.

In addition, according to an embodiment, when ultrasonic levitation is used, the output frequencies may be within a range of about 20 KHz to about 10 MHz. In addition, according to an embodiment, when a precise ultrasonic levitation is used, the output frequencies may be within a range of about 10 MHz to about 100 MHz. In addition, when the microelements 170 correspond to cells or fine particles, the output frequencies may be greater than or equal to 1 MHz. In addition, when the microelements 170 correspond to large objects, the output frequencies may be within a range of several tens of kHz.

The floating mask 150 may include the mask holes 152. The floating mask 150 may have a disk shape. For example, the floating mask 150 may have a circular disk shape. The floating mask 150 may include the mask holes 152 having sizes and shapes corresponding to element holes in the substrate 160. The floating mask 150 may include, for example, at least one of aluminum, stainless steel, Invar, or a high-rigidity organic material. Invar includes an alloy of nickel and metal.

The processor 210 controls overall operations of the element transfer device 100. The processor 210 may be implemented as one or more processors. The processor 210 may perform a certain operation by executing an instruction or command stored in memory (not shown). In addition, the processor 210 controls operations of components provided in the element transfer device 100.

The processor 210 is a component that controls a series of processes to operate the element transfer device 100, according to embodiments described hereinafter, and may include one or more processors. The one or more processors included in the processor 210 may be circuitry, such as a system on chip (SOC) or an integrated circuit (IC). The one or more processors included in the processor 210 may be a general-purpose processor such as a central processing unit (CPU), a microprocessor unit (MPU), an application processor (AP), or a digital signal processor (DSP), a dedicated processor for graphics such as a graphics processing unit (GPU) or a vision processing unit (VPU), a dedicated processor for artificial intelligence (AI) such as a neural processing unit (NPU), or a dedicated processor for communication such as a communication processor (CP). When the one or more processors included in the processor 210 are dedicated processors for AI, the dedicated processors for AI may be designed with hardware structures specialized for processing a specific AI model.

The processor 210 may write data to the memory and read the data stored in the memory, and in particular, may process data according to a predefined operation rule or AI model by executing a program or at least one instruction stored in the memory. Accordingly, the processor 210 may perform operations described in the following embodiments, and in subsequent embodiments, operations described as being performed by the element transfer device 100 or detailed components included in the element transfer device 100 may be considered as operations that are controlled by the processor 210, unless otherwise specified.

The processor 210 may generate and output drive signals to the plurality of vibration sources 130. The drive signals may be output to the plurality of vibration sources 130. According to an embodiment, the drive signals may be output to the signal amplifier 140, and the signal amplifier 140 may output the amplified drive signals to the plurality of vibration sources 130. The processor 210 may generate a pulse signal for controlling a waveform of vibrational energy of the plurality of vibration sources 130. The processor 210 may generate a pulse signal by using a certain function generator.

The processor 210 may control behavior of the floating mask 150 or behavior of the microelements 170 by adjusting frequencies of standing waves output from the plurality of vibration sources 130. In a dispersion operation, the processor 210 may output vibration from at least one of the plurality of vibration sources 130 to rotate or reciprocally rotate the floating mask 150. In addition, in a transfer operation, the processor 210 may set a target movement path of the microelements 170 and may control the plurality of vibration sources 130 to move the microelements 170 along the target movement path.

The container 120 may be implemented to be replaceable in the element transfer device 100. According to an embodiment, the container 120 may be replaced with various containers 120 of different specifications or sizes. The container 120 may be implemented as a disposable container. The container 120 may be provided with a fixing structure for fixing a substrate.

The plurality of vibration sources 130 may be arranged in a predefined arrangement on a certain support structure. The plurality of vibration sources 130 may be arranged on a plurality of concentric circles on the support structure. The support structure may have a structure for fixing the container 120 at a center of the concentric circles.

The processor 210 may be electrically connected to the plurality of vibration sources 130. According to an embodiment, the processor 210 may be integrally provided with the plurality of vibration sources 130. In addition, according to an embodiment, the processor 210 may be arranged in a certain external device electrically connected to the plurality of vibration sources 130. The external device may correspond to, for example, an electronic device such as a computer, a tablet personal computer (PC), a laptop computer, or a communication terminal.

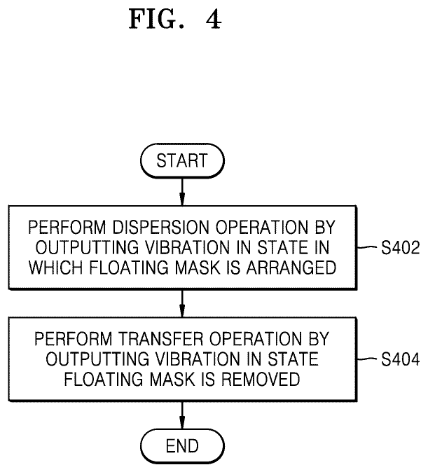

FIG. 4 is a flowchart illustrating a method for controlling an element transfer device, according to an embodiment.

According to an embodiment, a method for controlling element transfer device may be performed by the element transfer device 100 according to an embodiment. In addition, the method for controlling the element transfer device, according to an embodiment, may be performed by a certain electronic device (for example, a desktop PC, a laptop PC, a tablet PC, or a communication terminal) including a processor and memory. Throughout the specification, an embodiment in which the method for controlling the element transfer device is performed by the element transfer device 100 according to an embodiment is mainly described, but embodiments are not limited thereto.

In operation S402, the element transfer device 100 outputs vibrations from at least some of the plurality of vibration sources 130 in a state in which the floating mask 150 is arranged on the substrate 160. Before performing a dispersion operation, the substrate 160 may be arranged in the container 120, and the floating mask 150 may be arranged on the substrate 160. In addition, the substrate 160 and the floating mask 150 may be immersed in the fluid. In addition, the microelements 170 may be provided onto the floating mask 150. The microelements 170 may be provided onto the floating mask 150 by using a certain physical tool before performing the dispersion operation. The microelements 170 may be randomly dispersed in the fluid.

The element transfer device 100 may vibrate, rotate, or reciprocally rotate the floating mask 150 by performing a predefined dispersion operation of outputting vibration from at least one of the plurality of vibration sources 130. Operations of the element transfer device 100 according to a plurality of dispersion modes in the dispersion operation will be described layer.

While performing the dispersion operation, the microelements 170 pass through the floating mask 150 via the mask holes 152 in the floating mask 150 and move onto the substrate 160. The microelements 170 may move onto the substrate 160 in the fluid. As the microelements 170 move onto the substrate 160 via the mask holes 152 in the floating mask 150, the microelements 170 may be more uniformly distributed on the substrate 160.

When the dispersion operation in operation S402 ends, the floating mask 150 may be removed from the container 120. After the floating mask 150 is removed, the element transfer device 100 performs a transfer operation in operation S404. In the transfer operation, the element transfer device 100 controls the microelements 170 to be transferred into the element holes in the substrate 160. The element transfer device 100 controls the microelements 170 to be transferred into the element holes in the substrate 160, by outputting vibrations from the plurality of vibration sources 130 according to a certain transfer mode. The element transfer device 100 may capture, from above the substrate 160, an image of the substrate 160 to obtain the captured image. The element transfer device 100 may obtain information about a transfer state of the substrate 160 based on the captured image and may select and perform a transfer mode to move the microelements 170 to empty element holes. The operation of selecting and performing the transfer mode will be described later.

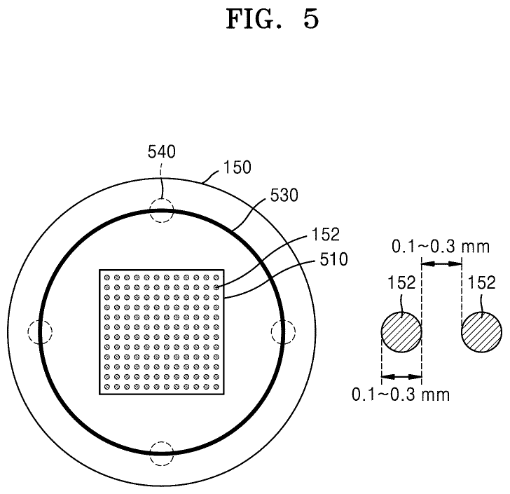

FIG. 5 is a diagram illustrating a structure of a floating mask according to an embodiment.

According to an embodiment, the floating mask 150 may have a circular disk shape. The floating mask 150 may include, for example, aluminum. The floating mask 150 may have, for example, a diameter of about 5 cm to about 20 cm. For example, the floating mask 150 may have a diameter of 8.4 cm. In addition, the floating mask 150 may have, for example, a thickness of 150 μm. In addition, the floating mask 150 is non-magnetic, and its surface may be polished.

The floating mask 150 may include the mask holes 152 in a central mask hole area 510. According to an embodiment, the mask hole area 510 may have a size and shape corresponding to an element hole area in which element holes are formed in the substrate 160. In addition, according to an embodiment, the mask hole area 510 may be greater than the element hole area by a certain size. For example, the mask hole area 510 may be greater than the element hole area by about 5% to about 10%.

The shape and size of the mask hole area 510 may be variously determined. The mask hole area 510 may have, for example, a square shape, a rectangular shape, a rhombus shape, a circular shape, an oval shape, a hexagonal shape, or an octagonal shape. In addition, the size of the mask hole area 510 may be, for example, about 2 cm to about 10 cm. The mask hole area 510 may have, for example, a square shape with sides of a length of 3 cm.

According to an embodiment, the sizes of the mask holes 152 may be determined according to the sizes of the microelements 170. The mask holes 152 have sizes that allow the microelements 170 to pass therethrough. For example, for use in a contact process, the mask holes 152 may have sizes that are 0% to about 15% greater than the sizes of the microelements 170. When for use in a non-contact process to uniformly disperse the microelements 170 on the substrate 160, the mask holes 152 may have, for example, sizes of about 0.1 mm to about 0.3 mm. In addition, the mask holes 152 may have, for example, oval shapes, quadrangular shapes, or hexagonal shapes. According to an embodiment, the mask holes 152 may have circular shapes. In addition, the mask holes 152 may have diameters of 200 μm.

A spacing, that is, a pitch, between the mask holes 152 may be determined according to the sizes of the mask holes 152. The spacing between the mask holes 152 may be determined to be, for example, the same as the sizes of the mask holes 152. The mask holes 152 may have, for example, sizes of about 0.1 mm to about 0.3 mm.

According to an embodiment in which the process is performed in a non-contact manner, the floating mask 150 may be provided with a spacer 530 on a surface thereof facing the substrate 160. When the floating mask 150 is arranged on the substrate 160, the spacer 530 supports the floating mask 150 to maintain a spacing between the floating mask 150 and the substrate 160.

According to an embodiment, the spacer 530 may correspond to an O-ring. The spacer 530 may have a thickness of about 0.1 cm to about 1 cm. In addition, the spacer 530 may be arranged along an outer periphery of the floating mask 150 to avoid interference with the mask hole area 510.

In addition, according to an embodiment, the floating mask 150 may include a plurality of lifting members 540. The lifting members 540 are provided in the floating mask 150 such that the floating mask 150 may be grasped when the floating mask 150 is removed from the container 120 after a dispersion operation. The lifting members 540 may be implemented in the form of protrusions, handles, or rings. According to an embodiment, the lifting members 540 may be arranged on a surface opposite to the surface of the floating mask 150 on which the spacer 530 is provided. The lifting members 540 may be arranged on a surface opposite to one surface of the floating mask 150 facing the substrate 160.

The lifting members 540 may be arranged to avoid interference with the mask hole area 510. The lifting members 540 may be arranged at certain points adjacent to the outer periphery of the floating mask 150. According to an embodiment, two lifting members 540 may be arranged adjacent to the outer periphery of the floating mask 150 and may be respectively arranged on opposite sides. In addition, according to an embodiment, four lifting members 540 may be arranged adjacent to the outer periphery of the floating mask 150 and may be respectively arranged at 90-degree intervals. According to an embodiment, the lifting members 540 may be arranged about 5 mm to about 10 mm inward from the outer periphery of the floating mask 150. For example, the lifting members 540 may be arranged 5 mm inward from the outer periphery of the floating mask 150.

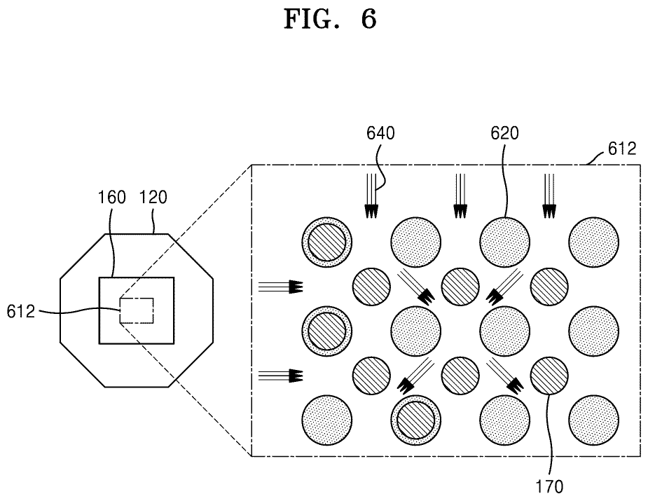

FIG. 6 is a diagram illustrating a substrate, which is arranged within a container, and microelements, according to an embodiment.

FIG. 6 illustrates an enlarged view of a first area 612 of the substrate 160 fixed to the container 120.

According to an embodiment, the container 120 may accommodate the substrate 160. The container 120 has a certain fixing structure, and the substrate 160 may be fixed to the container 120 by using the fixing structure. The substrate 160 may be referred to as an interposer. The substrate 160 may correspond to an Si interposer. According to an embodiment, the container 120 may be in the form of a cartridge in which the substrate 160 is integrally formed. When transferring of the microelements 170 onto the substrate 160 is completed in the cartridge, the microelements 170 transferred onto the substrate 160 within the cartridge may be transferred onto a certain other substrate.

The substrate 160 includes a plurality of element holes 620 in which the microelements 170 may be accommodated and fixed. The plurality of element holes 620 are formed as recesses in a surface of the substrate 160. The plurality of element holes 620 are formed to have shapes corresponding to the microelements 170 to allow the microelements 170 to be seated or fixed therein. The plurality of element holes 620 may be formed in the substrate 160 in a certain two-dimensional array form. According to an embodiment, when the microelements 170 are mini-LEDs having sizes of at least 70 μm, the substrate 160 may have a structure in which an elastic film is placed on a glass substrate and a fine metal mesh (FMM) is placed on the elastic film. In addition, according to an embodiment, when the microelements 170 correspond to micro LEDs, the substrate 160 may have a structure where a recessed pattern is formed directly on a silicon substrate.

In FIG. 6, the first area 612 of the substrate 160 is enlarged and is illustrated on the right. Referring to the enlarged view of the first area 612, behavior of the microelements 170 is described.

When vibrational energy is output from the plurality of vibration sources 130, the output vibrational energy is transmitted to the container 120, such that forces 640 are applied to the microelements 170 within the fluid. The forces and directions applied to the microelements 170 by the vibrational energy cause the microelements 170 to move into the element holes 620 in the substrate 160, wherein the microelements 170 are seated in the element holes 620 having shapes that match the microelements 170. The microelements 170 may move or rotate due to the forces 640 applied by the vibrational energy.

As such, for the microelements 170 to be transferred into the element holes 620 in the substrate 160, it is important that the microelements 170 be uniformly distributed on the substrate 160. When the microelements 170 are not uniformly distributed on the substrate 160 and are locally concentrated, a large number of residual microelements 170 that have not been transferred may remain distributed in areas where the microelements 170 are concentrated, thereby hindering movement of the microelements 170. In addition, in areas where the microelements 170 are not distributed, a large number of element holes 620 may remain empty due to a lack of microelements 170. According to an embodiment, by uniformly distributing the microelements 170 on the substrate 160 via the floating mask 150, a transfer success ratio of the element holes 620 in the substrate 160 may be increased.

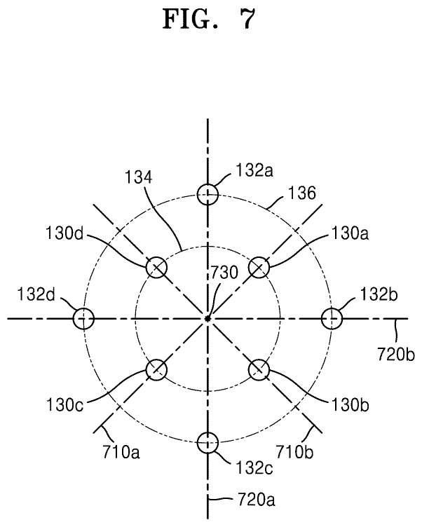

FIG. 7 is a diagram illustrating a container and a plurality of vibration sources, according to an embodiment.

Throughout the specification, an embodiment in which four vibration sources 130 are arranged on each of two concentric circles is mainly described. In addition, throughout the specification, an embodiment in which the eight vibration sources 130 are arranged to respectively correspond to corners of the container 120 having a regular octagonal shape is mainly described. However, the number of concentric circles and the number of vibration sources 130 may vary and are not limited to those disclosed in the embodiment.

According to an embodiment, the plurality of vibration sources 130 may be arranged on the plurality of concentric circles 134 and 136. The plurality of concentric circles 134 and 136 share a same center point 730 and have different radii. The first circle 134 may have a radius of a first distance, and the second circle 136 may have a radius of a second distance.

The plurality of vibration sources 130 include: the vibration sources 130a, 130b, 130c, and 130d of the first group arranged on the first circle 134; and the vibration sources 132a, 132b, 132c, and 132d of the second group arranged on the second circle 136. The vibration sources 130a, 130b, 130c, and 130d of the first group may include at least one pair of vibration sources 130a, 130b, 130c, and 130d that are arranged to face each other on at least one long axis. According to an embodiment, a pair of the vibration sources 132a and 132c of the second group may be arranged on a first long axis 720a, and a pair of the vibration sources 132b and 132d of the second group may be arranged on a second long axis 720b. In addition, a pair of the vibration sources 130a and 130c of the first group may be arranged on a first short axis 710a, and a pair of the vibration sources 130b and 130d of the first group may be arranged on a second short axis 710b. The first short axis 710a, the first long axis 720a, the second short axis 710b, and the second long axis 720b may be arranged in this stated order and may each form an angle of 45° with its neighboring axis.

According to an embodiment, by arranging a pair of vibration sources, from among the vibration sources 130, at positions facing each other and arranging the vibration sources 130 on the plurality of concentric circles 134 and 136, the vibration sources 130a, 130b, 130c, and 130d of the first group on the short axes 710a and 710b, which are located between the vibration sources 132a, 132b, 132c, and 132d of the second group on the long axes 720a and 720b, may act as a spring. Accordingly, the element transfer device 100 is able to form reflected waves in areas rotated by about 20° to about 90° due to vibrational energy output from the vibration sources 130. In addition, the reflected waves formed in this manner form composite vectors in an acoustic potential field over time, thereby causing a dispersion pattern of the microelements 170 to change periodically. In addition, dispersion of the microelements 170 may be more rapidly induced by additionally applying a beat frequency of about 1 Hz to about 10 Hz to induce a torque generation. The beat frequency refers to a frequency difference between one vibration source and another vibration source, from among the vibration sources 130, or a frequency difference over time, in a vibration output sequence of the vibration sources 130. By applying the beat frequency, vibrational energy output from the plurality of vibration sources 130 manifests as a composite waveform, and a swing effect corresponding to the width of a wavelength difference resulting from a frequency difference between two vibrations is obtained, and accordingly, a force field that may further probabilistically accelerate the dispersion of the microelements 170 may be provided. When vibrational energy from the plurality of vibration sources 130 is applied to a fluid within the container 120, a total acoustical pressure is represented by Equation 1.

$$P ( x , t ) = {P}_{0} cos ( {ω}_{2} t + \frac{{ω}_{2}}{{c}_{0}} x ) + {P}_{0} cos ( ω \text{?} t + \frac{ω \text{?}}{{c}_{0}} x ) \qquad [ Equation 1 ]$$

$$\text{?} \text{indicates text missing or illegible when filed}$$

In Equation 1, P₀ refers to a wave amplitude, an angular velocity ω₁ equals to 2πf₁ (rad/s), an angular velocity ω₂ equals to 2π*f₂ (rad/s), t(s) refers to time, x(m)ᵢ refers to a distance from the vibration source 130, and c₀ refers to a sound wave propagation speed in a medium. Here, f₁ equals to the sum of f₂ and Δf, and Δf refers to a beat frequency.

In Equation 1, when the sound wave propagation speed in the medium satisfies ω₁=ω₂+ε and ω=(ω₁+ω₂)/2 is satisfied, an induced force applied to all of the microelements 170 is represented by Equation 2.

$${F}_{x} ( x , t ) = 4 π {kr}^{3} ( \frac{{P}_{0}^{2}}{4 {ρ}_{0} {c}_{0}^{2}} ) Φ ( ρ , c ) sin ( 2 kx - ϵ t ) \qquad [ Equation 2 ]$$

In Equation 2, r refers to the radius (m) of each microelement 170, ρ₀ refers to the density (kg/m³) of the fluid, c refers to a sound speed in each microelement 170, φ(ρ,c) refers to an acoustic contrast factor, and k=ω/c₀ refers to a wave number (m−¹). P_{D} is an acoustic pressure field and may correspond to 2P_{O}. P_{O} corresponds to an average peak amplitude of two waves with a beat frequency. The force field moves from a high-frequency vibration source to a low-frequency vibration source at a constant speed v=ε/2k in units of m/s. When frequencies of excitation are given as f₁=f₂+Δf and f=(f₁+f₂)/2 (Hz) is satisfied, the speed of a vibration pattern satisfies v=(Δf/2f) c₀.

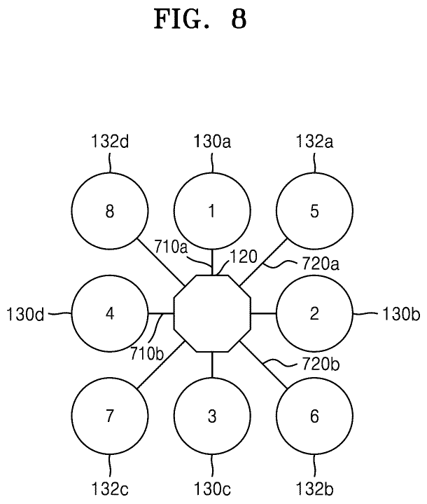

FIG. 8 is a diagram illustrating an arrangement of a plurality of vibration sources according to an embodiment.

According to an embodiment, the plurality of vibration sources 130 may be arranged as illustrated in FIG. 8. The plurality of vibration sources 130 include the vibration sources 130a, 130b, 130c, and 130d of the first group and the vibration sources 132a, 132b, 132c, and 132d of the second group.

The vibration sources 130a, 130b, 130c, and 130d of the first group include the first vibration source 130a, the second vibration source 130b, the third vibration source 130c, and the fourth vibration source 130d. The first vibration source 130a and the third vibration source 130c are a pair of vibration sources arranged to face each other on the first short axis 710a. The first vibration source 130a and the third vibration source 130c are arranged at the same distance from a center of concentric circles on which the plurality of vibration sources 130 are arranged. The second vibration source 130b and the fourth vibration source 130d are a pair of vibration sources arranged to face each other on the second short axis 710b. The second vibration source 130b and the fourth vibration source 130d are arranged at the same distance from the center of the concentric circles on which the plurality of vibration sources 130 are arranged.

The vibration sources 132a, 132b, 132c, and 132d of the second group include the fifth vibration source 132a, the sixth vibration source 132b, the seventh vibration source 132c, and the eighth vibration source 132d. The fifth vibration source 132a and the seventh vibration source 132c are a pair of vibration sources arranged to face each other on the first long axis 720a. The fifth vibration source 132a and the seventh vibration source 132c are arranged at the same distance from the center of the concentric circles on which the plurality of vibration sources 130 are arranged. The sixth vibration source 132b and the eighth vibration source 132d are a pair of vibration sources arranged to face each other on the second long axis 720b. The sixth vibration source 132b and the eighth vibration source 132d are arranged at the same distance from the center of the concentric circles on which the plurality of vibration sources 130 are arranged.

In an embodiment, a plurality of transfer modes are defined based on the arrangement of the plurality of vibration sources 130 illustrated in FIG. 8.

According to an embodiment, a dispersion mode may define at least one of whether each of the plurality of vibration sources 130 operates, an output frequency of each of the plurality of vibration sources 130, an output cycle thereof, and an output time thereof. The vibration source 130 that outputs vibration in each dispersion mode, an output frequency, and a timing may be pre-stored in memory of the element transfer device 100. The element transfer device 100 may perform operations of respective dispersion modes by controlling the vibration source 130 according to a sequence stored in the memory.

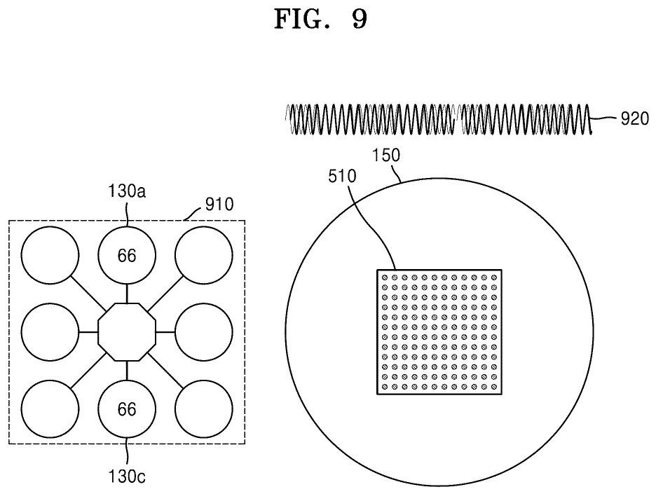

FIGS. 9 to 11 are diagrams for illustrating operations of respective dispersion modes. Referring to FIGS. 9 to 11, a plurality of dispersion modes are described. In FIGS. 9 to 11, each circle represents the vibration source 130, and the octagonal shape represents the container 120. In addition, an arrangement of the vibration sources 130 in FIGS. 9 to 11 corresponds to the arrangement of the vibration sources 130 described with reference to FIG. 8. A number written in a circle corresponding to the vibration source 130 indicates an output frequency in Hz, and an empty circle indicates a state in which no vibration is output.

FIG. 9 is a diagram illustrating an operation of a first dispersion mode according to an embodiment.

A first dispersion mode 910 is a mode that vibrates a pair of vibration sources on either a short axis or a long axis at a certain frequency. According to an embodiment, in the first dispersion mode 910, the element transfer device 100 may output a vibration of a first frequency from the first vibration source 130a and the third vibration source 130c, which are a pair of vibration sources on a first short axis 130a. For example, the first frequency may be 66 Hz. The first dispersion mode 910 is a mode that applies vibration to the floating mask 150. In the first dispersion mode 910, vibrational energy 920 may be transmitted to the floating mask 150 and the fluid without involving horizontal rotational motion of the floating mask 150. In the first dispersion mode 910, as the floating mask 150 vibrates, the microelements 170 on the floating mask 150 may move onto the substrate 160 via the mask holes.

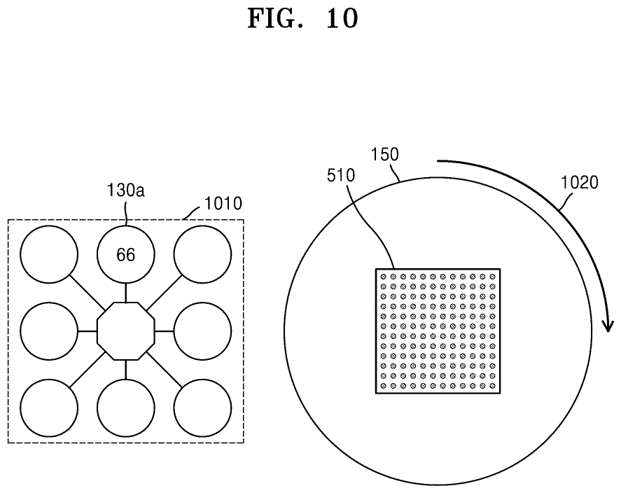

FIG. 10 is a diagram illustrating an operation of a second dispersion mode according to an embodiment.

A second dispersion mode 1010 is a mode that outputs a vibration from one of the plurality of vibration sources 130. For example, the element transfer device 100 may output a vibration of a first frequency from the first vibration source 130a in the second dispersion mode 1010. For example, the first frequency may be 66 Hz. The second dispersion mode 1010 rotates the floating mask 150 clockwise or counterclockwise. In the second dispersion mode 1010, as the floating mask 150 rotates, the microelements 170 on the floating mask 150 may move onto the substrate 160 via the mask holes. The second dispersion mode 1010 refers to a phenomenon in which, by utilizing an asymmetric vibration pattern or nonlinear effects, a force applied to the floating mask 150 on a wave is made to move in a specific direction. According to an embodiment, the element transfer device 100 may generate an asymmetric interference pattern by simultaneously applying two or more frequencies from one vibration source 130. In this case, due to a frequency difference, an asymmetric motion pattern, such as a Lissajous curve (a geometric figure formed by synthesis of two waves with a phase difference), may be generated, and rotation of the floating mask 150 may be induced using the asymmetric motion pattern.

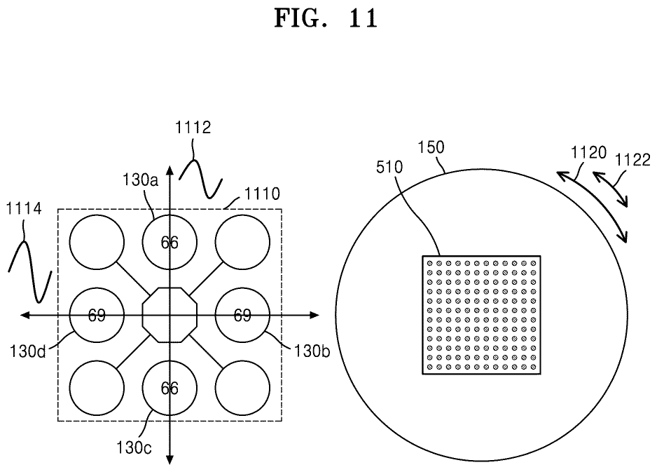

FIG. 11 is a diagram illustrating an operation of a third dispersion mode according to an embodiment.

A third dispersion mode 1110 is a mode that outputs a vibration of a first frequency from a pair of the vibration sources 130a and 130c on the first short axis 710a and outputs a vibration of a second frequency from a pair of the vibration sources 130b and 130d on the second short axis 710b. For example, in the third dispersion mode 1110, the element transfer device 100 may output a vibration of 66 Hz from the pair of the vibration sources 130a and 130c on the first short axis 710a and may output a vibration within a range of about 67 Hz to about 69 Hz from the pair of the vibration sources 130b and 130d on the second short axis 710b. The third dispersion mode 1110 reciprocally rotates the floating mask 150. In the third dispersion mode 1110, as the floating mask 150 reciprocally rotates, the microelements 170 on the floating mask 150 may move onto the substrate 160 via the mask holes. The third dispersion mode 1110 uses a physical phase difference between the vibration output from the pair of the vibration sources 130a and 130c on the first short axis 710a and the vibration output from the pair of the vibration sources 130b and 130d on the second short axis 710b.

According to an embodiment, the amplitude of a first vibration 1112 output from the pair of the vibration sources 130a and 130c on the first short axis 710a and the amplitude of a second vibration 1114 output from the pair of the vibration sources 130b and 130d on the second short axis 710b may be set differently. The element transfer device 100 may control directionality of the reciprocal rotational motion by adjusting the amplitudes of the first vibration 1112 and the second vibration 1114. The element transfer device 100 may control the floating mask 150 to perform a reciprocal rotational motion with either clockwise or counterclockwise directionality based on the amplitude difference.

According to an embodiment, the amplitude of the reciprocal rotational motion may vary based on a beat frequency corresponding to a frequency difference between the first vibration 1112 and the second vibration 1114. For example, the floating mask 150 performs a reciprocal rotational motion with a first amplitude 1122 when the beat frequency is 1 Hz, and the floating mask 150 performs a reciprocal rotational motion with a second amplitude 1120 when the beat frequency is 3 Hz. As the beat frequency increases, the amplitude of the reciprocal rotational motion may increase. For example, the amplitude of the reciprocal rotational motion may correspond to about 15 degrees to about 20 degrees when the beat frequency is 3 Hz.

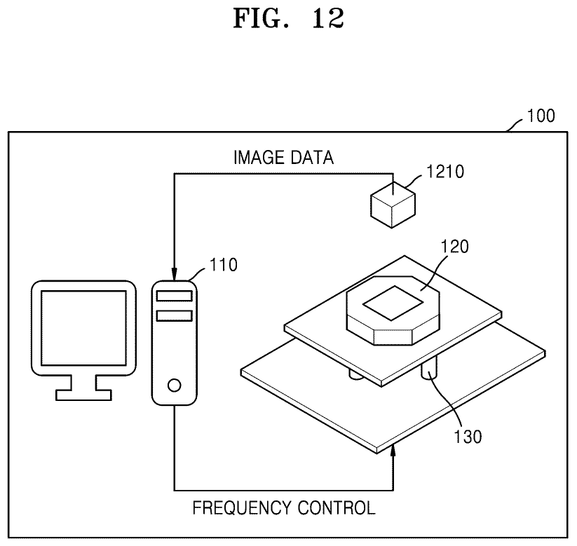

FIG. 12 is a diagram illustrating a structure of an element transfer device according to an embodiment.

According to an embodiment, the element transfer device 100 may include the computing device 110, the container 120, the plurality of vibration sources 130, and a camera 1210. The computing device 110 includes the processor 210 that controls the element transfer device 100.

The camera 1210 photoelectrically converts incident light to generate an electrical image signal. The camera 1210 may include at least one lens, a lens driver, and an image sensor. The camera 1210 may include at least one camera 1210. The camera 1210 generates captured image data and outputs the captured image data to the processor 210.

The camera 1210 may be arranged to capture an image of a top surface of the substrate 160 arranged in the container 120. After the floating mask 150 is removed from the container 120, while a transfer operation is performed, the camera 1210 may capture an image of the top surface of the substrate 160. The camera 1210 may be fixed at a certain position to face a top surface of the container 120. The camera 1210 may be arranged such that a field of view (FOV) may be adjusted, that is, an imaging direction may be adjusted. The camera 1210 may capture a still image or a moving image based on a control signal from the processor 210. The camera 1210 may transmit the captured image to the computing device 110.

The processor 210 may receive the captured image captured by the camera 1210. The processor 210 determines a transfer state of the microelements 170 being transferred onto the substrate 160, by using the captured image. The transfer state refers to a ratio of element holes 620 in which transferring of the microelements 170 has been completed, with respect to all of the element holes 620 in the substrate 160. The processor 210 recognizes the element holes 620 by using the captured image and determines whether the microelements 170 have been transferred into each element hole 620. The processor 210 may recognize the element holes 620 by using a certain image recognition algorithm and may determine whether transferring of the microelements 170 into each element hole 620 has been completed. According to an embodiment, the computing device 110 may pre-store information about the number and arrangement of element holes 620 in a certain memory, and the processor 210 may identify positions of the element holes 620 by using the pre-stored information. The processor 210 may calculate a transfer state by calculating a ratio of transferred element holes 620 by using the number of transferred element holes 620 relative to the number of all of the element holes 620.

According to an embodiment, the processor 210 may recognize residual microelements 170 that have not been transferred, by using the captured image. The processor 210 may obtain position information and distribution information of the residual microelements 170. The processor 210 may output vibrations from the plurality of vibration sources 130 to transfer the residual microelements 170 into empty element holes 620.

According to an embodiment, the element transfer device 100 may control the plurality of vibration sources 130 by using a plurality of dispersion modes or transfer modes that define operations of the plurality of vibration sources 130. The plurality of dispersion modes or transfer modes may define at least one of whether each of the plurality of vibration sources 130 operates, an output frequency of each of the plurality of vibration sources 130, an output cycle thereof, or an output time thereof. The element transfer device 100 may move the microelements 170 in desired directions or patterns by using the plurality of dispersion modes or transfer modes. The plurality of dispersion modes or transfer modes are described in detail below.

According to an embodiment, the element transfer device 100 includes at least one connection plate arranged between the plurality of vibration sources 130 and the container 120. According to an embodiment, the at least one connection plate includes eight connection plates, which individually connect each of the vibration sources 130 to the container 120. In addition, according to an embodiment, the at least one connection plate is implemented as a single plate that is in contact with all of the vibration sources 130.

According to an embodiment, the processor 210 determines a transfer mode, based on the transfer state and the distribution of the residual microelements 170, which are obtained by using the captured image. According to an embodiment, the processor 210 may control behavior of the residual microelements 170 according to a transfer mode sequence in which the plurality of transfer modes are sequentially performed.

The element transfer device 100 may repeat operations of capturing an image, determining a transfer state of the substrate 160, and then determining and performing a transfer mode until reaching a target transfer ratio. The target transfer ratio may be a predefined value, for example, 99.5%.

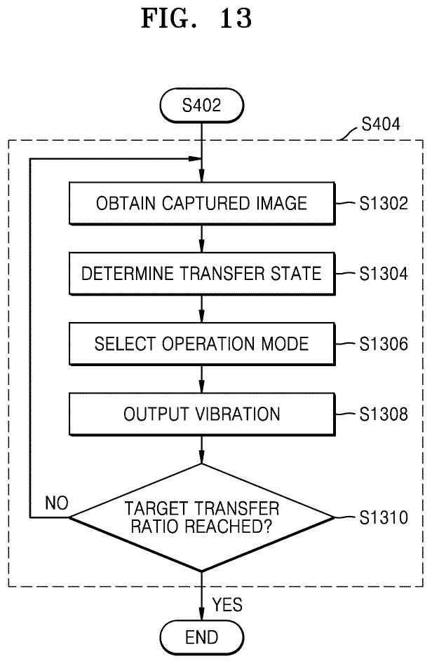

FIG. 13 is a flowchart illustrating a transfer operation according to an embodiment.

According to an embodiment, the element transfer device 100 may perform the transfer operation in operation S404 when the dispersion operation in operation S402 described above with reference to FIG. 4 is completed. According to an embodiment, the transfer operation may include operations S1302, S1304, S1306, S1308, and S1310.

In operation S1302, the element transfer device 100 captures an image of the substrate 160 within the container 120 by using the camera 1210 and obtains the captured image. The captured image may be an image of a top surface of the substrate 160.

Next, in operation S1304, the element transfer device 100 determines a transfer state of the substrate 160 by using the captured image. The element transfer device 100 may determine a transfer state of the substrate 160 by calculating a ratio of element holes 620 in which element transfer has been completed. In addition, according to an embodiment, the element transfer device 100 may detect residual microelements 170 in a fluid within the container 120 by using the captured image. The element transfer device 100 may identify positions or distribution of the residual microelements 170.

In addition, according to an embodiment, the element transfer device 100 may detect residual element holes into which the microelements 170 have not been transferred, from among the element holes 620 in the substrate 160, by using the captured image. The element transfer device 100 may detect at least one of element holes into which the microelements 170 have been transferred and element holes into which the microelements 170 have not been transferred, from among the element holes 620 in the substrate 160, by using the captured image. The element transfer device 100 may classify each element hole 620 as a transfer-completed element hole or a residual element hole, according to a result of the detection. The element transfer device 100 may identify positions or distribution of the residual element holes.

Next, in operation S1306, the element transfer device 100 may select a transfer mode of the plurality of vibration sources 130, based on the transfer state of the substrate 160 and the positions of the residual microelements 170. Based on the transfer state of the element transfer device 100 and the positions of the residual microelements, target positions to which the residual microelements are to be moved may be determined, and a transfer mode for moving the residual microelements to the target positions may be selected.

According to an embodiment, the element transfer device 100 may select a transfer mode based on the transfer state, the positions of the residual microelements, and the positions of the residual element holes. The element transfer device 100 may set target positions to which the residual microelements are to be moved, based on the positions of the residual microelements and the positions of the residual element holes. The element transfer device 100 may select a transfer mode, based on the current positions of the residual microelements and the target positions to which the residual microelements are to be moved.

According to an embodiment, the element transfer device 100 may select a transfer mode by using an AI model. The element transfer device 100 may input the captured image to the AI model, and the AI model may output the selected transfer mode based on the captured image. The AI model may be machine-learned by training data including a plurality of captured images and a plurality of transfer modes. According to an embodiment, the AI model may use a proximal policy optimization (PPO) algorithm. In addition, according to an embodiment, the AI model may use at least one of trust region policy optimization (TRPO), advantage actor critic (A2C), and deep Q network (DQN).

Next, in operation S1308, the element transfer device 100 outputs vibrations from the plurality of vibration sources 130 by controlling the plurality of vibration sources 130 in the selected transfer mode. The processor 210 controls the plurality of vibration sources 130 in a manner defined in the selected transfer mode. The processor 210 generates a drive signal with an output frequency defined in the selected transfer mode and outputs the generated drive signal to the vibration source 130 that outputs vibration. The processor 210 controls the plurality of vibration sources 130 to output vibrations in a set pattern during a preset time or cycle.

When the vibrations are output from the plurality of vibration sources 130, the vibrations are transmitted from the plurality of vibration sources 130 to the container 120 via a connection plate and transmitted to the fluid within the container 120, thereby inducing waves within the fluid. The microelements 170 within the fluid are moved by the waves induced within the fluid. The operation of outputting the vibrations from the plurality of vibration sources 130 is performed for a preset period of time.

Next, in operation S1310, the element transfer device 100 determines whether the transfer state of the substrate 160 has reached a target transfer ratio. After the outputting of the vibrations is completed in operation S1308, the element transfer device 100 may obtain a captured image of the substrate 160 again and may determine whether the transfer state of the substrate 160 has reached the target transfer ratio, based on the captured image.

The element transfer device 100 repeats operations S1302, S1304, S1306, and S1308 when the transfer state of the substrate 160 has not reached the target transfer ratio. The element transfer device 100 may repeat operations S1302, S1304, S1306, S1308, and S1310 until the transfer state reaches the target transfer ratio.

When it is determined that the transfer state of the substrate 160 has reached the target transfer ratio in operation S1310, the element transfer device 100 terminates the operations. According to an embodiment, when it is determined that the transfer state of the substrate 160 has reached the target transfer ratio, the element transfer device 100 may output a notification indicating that the transfer state of the substrate 160 has reached the target transfer ratio via a certain output interface or an external device. Next, a plurality of transfer modes are described.

In an embodiment, the plurality of transfer modes are defined based on the arrangement of the plurality of vibration sources 130 illustrated in FIG. 8.

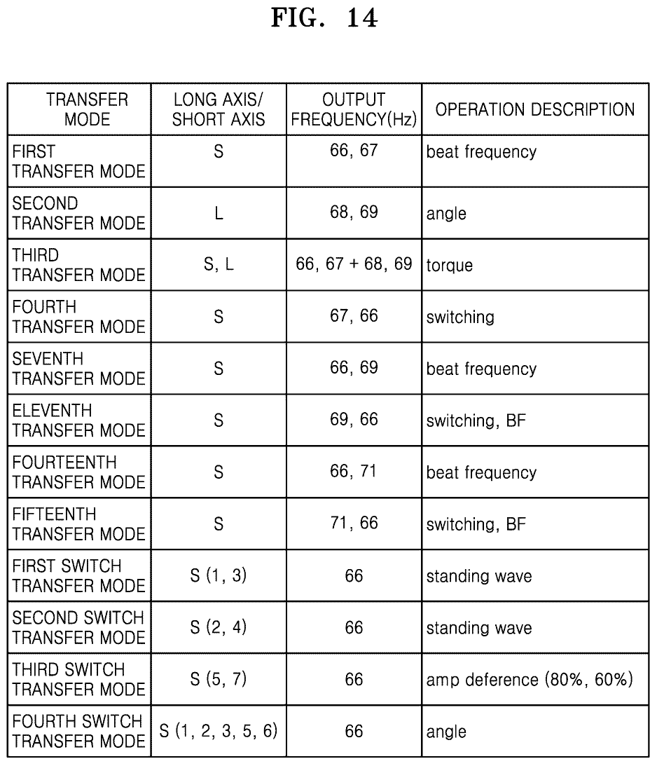

FIG. 14 is a diagram illustrating definitions of a plurality of transfer modes according to an embodiment.

According to an embodiment, the plurality of transfer modes may be defined by vibration sources, which output vibrations in each transfer mode, and output frequencies. The plurality of transfer modes are defined as illustrated in FIG. 14 and may be pre-stored in memory of the element transfer device 100.

The plurality of transfer modes may include at least one of a first transfer mode, a second transfer mode, a third transfer mode, a fourth transfer mode, a seventh transfer mode, an eleventh transfer mode, a fourteenth transfer mode, a fifteenth transfer mode, a first switch transfer mode, a second switch transfer mode, a third switch transfer mode, or a fourth switch transfer mode, or a combination thereof.

The first transfer mode is a transfer mode that vibrates the first vibration source 130a and the third vibration source 130c, which are a pair of vibration sources on the first short axis 710a, at a first frequency and vibrates the second vibration source 130b and the fourth vibration source 130d, which are a pair of vibration sources on the second short axis 710b, at a second frequency that is higher than the first frequency by a first beat frequency. For example, the first frequency may be 66 Hz, the second frequency may be 67 Hz, and the first beat frequency may be 1 Hz. The first transfer mode is a transfer mode that applies a beat frequency to a fluid within the container 120.

The second transfer mode is a transfer mode that vibrates the fifth vibration source 132a and the seventh vibration source 132c, which are a pair of vibration sources on the first long axis 720a, at a third frequency and vibrates the sixth vibration source 132b and the eighth vibration source 132d, which are a pair of vibration sources on the second long axis 720b, at a fourth frequency that is higher than the third frequency by the first beat frequency. For example, the third frequency may be 68 Hz, the fourth frequency may be 69 Hz, and the first beat frequency may be 1 Hz.

The third transfer mode is a transfer mode that vibrates the first vibration source 130a and the third vibration source 130c, which are a pair of vibration sources on the first short axis 710a, at the first frequency, vibrates the second vibration source 130b and the fourth vibration source 130d, which are a pair of vibration sources on the second short axis 710b, at the second frequency, vibrates the fifth vibration source 132a and the seventh vibration source 132c, which are a pair of vibration sources on the first long axis 720a, at the third frequency, and vibrates the sixth vibration source 132b and the eighth vibration source 132d, which are a pair of vibration sources on the second long axis 720b, at the fourth frequency. The third transfer mode is a transfer mode that applies a torque in the fluid within the container 120. In the third transfer mode, by operating all of the plurality of vibration sources 130, a dispersion pattern rotates over time.

The fourth transfer mode is a transfer mode that vibrates the pair of the vibration sources on the first short axis 710a at the second frequency and vibrates the pair of the vibration sources on the second short axis 710b at the first frequency. The fourth transfer mode is a transfer mode that applies a beat frequency to the fluid within the container 120 by switching the output frequencies of the first transfer mode between the pair of the vibration sources on the first short axis 710a and the pair of the vibration sources on the second short axis 710b.

The seventh transfer mode is a transfer mode that vibrates the pair of the vibration sources on the first short axis 710a at the first frequency and vibrates the pair of the vibration sources on the second short axis 710b at a fifth frequency that is higher than the first frequency by a second beat frequency. For example, the second beat frequency may be 3 Hz, and the fifth frequency may be 69 Hz. The seventh transfer mode is a transfer mode that applies a beat frequency to the fluid within the container 120.

The eleventh transfer mode is a transfer mode that vibrates the pair of the vibration sources on the first short axis 710a at the fifth frequency and vibrates the pair of the vibration sources on the second short axis 710b at the first frequency. The eleventh transfer mode is a transfer mode that applies a beat frequency to the fluid within the container 120 by switching the output frequencies of the first transfer mode between the pair of the vibration sources on the first short axis 710a and the pair of the vibration sources on the second short axis 710b.

The fourteenth transfer mode is a transfer mode that vibrates the pair of the vibration sources on the first short axis 710a at the first frequency and vibrates the pair of the vibration sources on the second short axis 710b at a sixth frequency that is higher than the first frequency by a third beat frequency. For example, the third beat frequency may be 5 Hz, and the sixth frequency may be 71 Hz. The fourteenth transfer mode is a transfer mode that applies a beat frequency to the fluid within the container 120.

The fifteenth transfer mode is a transfer mode that vibrates the pair of the vibration sources on the first short axis 710a at the sixth frequency and vibrates the pair of the vibration sources on the second short axis 710b at the first frequency. The fifteenth transfer mode is a transfer mode that applies a beat frequency to the fluid within the container 120 by switching the output frequencies of the fourteenth transfer mode between the pair of the vibration sources on the first short axis 710a and the pair of the vibration sources on the second short axis 710b.

The first switch transfer mode is a transfer mode that vibrates the pair of the vibration sources on the first short axis 710a at the first frequency. The first switch transfer mode generates a standing wave of the first frequency between the pair of the vibration sources on the first short axis 710a.

The second switch transfer mode is a transfer mode that vibrates the pair of the vibration sources on the second short axis 710b at the first frequency. The second switch transfer mode generates a standing wave of the first frequency between the pair of the vibration sources on the second short axis 710b.

The third switch transfer mode is a transfer mode that vibrates the pair of the vibration sources on the first long axis 720a at the first frequency and sets different signal amplification ratios between the two vibration sources of the pair of the vibration sources on the first long axis 720a. For example, the fifth vibration source 132a may output a vibration of the first frequency with an amplification ratio of 80%, and the seventh vibration source 132c may output a vibration of the first frequency with an amplification ratio of 60%.

The fourth switch transfer mode is a transfer mode that vibrates, at the first frequency, the pair of the vibration sources on the first short axis 710a and vibration sources included in either vibration sources of a third group or vibration sources of a fourth group, wherein the vibration sources of the third group and the vibration sources of the fourth group are divided by the first short axis 710a. For example, the vibration sources of the third group may include the fourth vibration source 130d, the seventh vibration source 132c, and the eighth vibration source 132d, and the vibration sources of the fourth group may include the second vibration source 130b, the fifth vibration source 132a, and the sixth vibration source 132b. According to an embodiment, the fourth switch transfer mode may be a transfer mode that vibrates the pair of the vibration sources on the first short axis 710a and the vibration sources of the fourth group at the first frequency. In other words, the fourth switch transfer mode may be a transfer mode that vibrates the first vibration source 130a, the second vibration source 130b, the third vibration source 130c, the fifth vibration source 132a, and the sixth vibration source 132b at the first frequency.

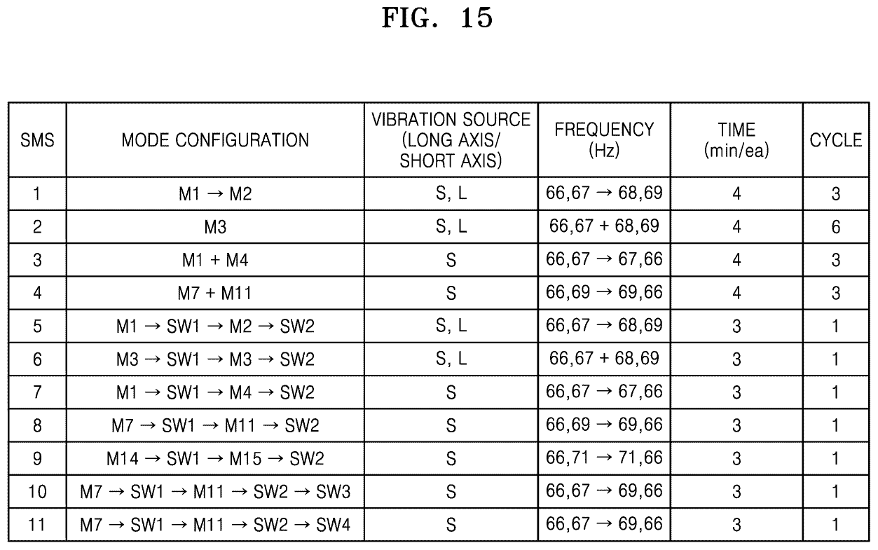

FIG. 15 is a diagram illustrating a plurality of transfer modes according to an embodiment.

According to an embodiment, a transfer mode may be defined as a sequence of the transfer modes described above with reference to FIG. 14. Throughout the specification, the transfer mode defined as the sequence of the transfer modes is referred to as a sequential mode shift (SMS) transfer mode.

According to an embodiment, the SMS transfer mode may include at least one of a first SMS transfer mode, a second SMS transfer mode, a third SMS transfer mode, a fourth SMS transfer mode, a fifth SMS transfer mode, a sixth SMS transfer mode, a seventh SMS transfer mode, an eighth SMS transfer mode, a ninth SMS transfer mode, a tenth SMS transfer mode, and an eleventh SMS transfer mode. Each SMS transfer mode may be defined by the type and order of an operation mode that is performed, an execution time of one cycle, and the number of cycle repetitions.

The first SMS transfer mode is a transfer mode in which the element transfer device 100 operates in a first transfer mode M1 and then operates in a second transfer mode M2. In the first SMS transfer mode, the element transfer device 100 may operate in the first transfer mode M1 for 4 minutes and then operate in the second transfer mode M2 for 4 minutes. In addition, in the first SMS transfer mode, the element transfer device 100 may repeat a cycle of operating in the first transfer mode M1 and the second transfer mode M2 three times.

The second SMS transfer mode is a transfer mode in which the element transfer device 100 operates in a third transfer mode M3. In the second SMS transfer mode, the element transfer device 100 may repeat a cycle of operating in the third transfer mode M3 for 4 minutes, six times.

The third SMS transfer mode is a transfer mode in which the element transfer device 100 operates in the first transfer mode M1 and then operates in a fourth transfer mode M4. In the third SMS transfer mode, the element transfer device 100 may operate in the first transfer mode M1 for 4 minutes and then operate in the fourth transfer mode M4 for 4 minutes. In addition, in the third SMS transfer mode, the element transfer device 100 may repeat a cycle of operating in the first transfer mode M1 and the fourth transfer mode M4 three times.

The fourth SMS transfer mode is a transfer mode in which the element transfer device 100 operates in a seventh transfer mode M7 and then operates in an eleventh transfer mode M11. In the fourth SMS transfer mode, the element transfer device 100 may operate in the seventh transfer mode M7 for 4 minutes and then operate in the eleventh transfer mode M11 for 4 minutes. In addition, in the fourth SMS transfer mode, the element transfer device 100 may repeat a cycle of operating in the seventh transfer mode M7 and the eleventh transfer mode M11 three times.

The fifth SMS transfer mode is a transfer mode in which the element transfer device 100 sequentially operates in the first transfer mode M1, a first switch transfer mode SW1, the second transfer mode M2, and a second switch transfer mode SW2. In the fifth SMS transfer mode, the element transfer device 100 may operate in the first transfer mode M1 for 3 minutes, operate in the first switch transfer mode SW1 for 3 minutes, operate in the second transfer mode M2 for 3 minutes, and then operate in the second switch transfer mode SW2 for 3 minutes. In addition, in the fifth SMS transfer mode, the element transfer device 100 may perform one cycle of operating in the first transfer mode M1, the first switch transfer mode SW1, the second transfer mode M2, and the second switch transfer mode SW2.

The sixth SMS transfer mode is a transfer mode in which the element transfer device 100 sequentially operates in the third transfer mode M3, the first switch transfer mode SW1, the third transfer mode M3, and the second switch transfer mode SW2. In the sixth SMS transfer mode, the element transfer device 100 may operate in the third transfer mode M3 for 3 minutes, operate in the first switch transfer mode SW1 for 3 minutes, operate in the third transfer mode M3 for 3 minutes, and then operate in the second switch transfer mode SW2 for 3 minutes. In addition, in the sixth SMS transfer mode, the element transfer device 100 may perform one cycle of operating in the third transfer mode M3, the first switch transfer mode SW1, the third transfer mode M3, and the second switch transfer mode SW2.

The seventh SMS transfer mode is a transfer mode in which the element transfer device 100 sequentially operates in the first transfer mode M1, the first switch transfer mode SW1, the fourth transfer mode M4, and the second switch transfer mode SW2. In the seventh SMS transfer mode, the element transfer device 100 may operate in the first transfer mode M1 for 3 minutes, operate in the first switch transfer mode SW1 for 3 minutes, operate in the fourth transfer mode M4 for 3 minutes, and then operate in the second switch transfer mode SW2 for 3 minutes. In addition, in the seventh SMS transfer mode, the element transfer device 100 may perform one cycle of operating in the first transfer mode M1, the first switch transfer mode SW1, the fourth transfer mode M4, and the second switch transfer mode SW2.

The eighth SMS transfer mode is a transfer mode in which the element transfer device 100 sequentially operates in the seventh transfer mode M7, the first switch transfer mode SW1, the eleventh transfer mode M11, and the second switch transfer mode SW2. In the eighth SMS transfer mode, the element transfer device 100 may operate in the seventh transfer mode M7 for 3 minutes, operate in the first switch transfer mode SW1 for 3 minutes, operate in the eleventh transfer mode M11 for 3 minutes, and then operate in the second switch transfer mode SW2 for 3 minutes. In addition, in the eighth SMS transfer mode, the element transfer device 100 may perform one cycle of operating in the seventh transfer mode M7, the first switch transfer mode SW1, the eleventh transfer mode M11, and the second switch transfer mode SW2.

The ninth SMS transfer mode is a transfer mode in which the element transfer device 100 sequentially operates in a fourteenth transfer mode M14, the first switch transfer mode SW1, a fifteenth transfer mode M15, and the second switch transfer mode SW2. In the ninth SMS transfer mode, the element transfer device 100 may operate in the fourteenth transfer mode M14 for 3 minutes, operate in the first switch transfer mode SW1 for 3 minutes, operate in the fifteenth transfer mode M15 for 3 minutes, and then operate in the second switch transfer mode SW2 for 3 minutes. In addition, in the ninth SMS transfer mode, the element transfer device 100 may perform one cycle of operating in the fourteenth transfer mode M14, the first switch transfer mode SW1, the fifteenth transfer mode M15, and the second switch transfer mode SW2.

The tenth SMS transfer mode is a transfer mode in which the element transfer device 100 sequentially operates in the seventh transfer mode M7, the first switch transfer mode SW1, the eleventh transfer mode M11, the second switch transfer mode SW2, and a third switch transfer mode SW3. In the tenth SMS transfer mode, the element transfer device 100 may operate in the seventh transfer mode M7 for 3 minutes, operate in the first switch transfer mode SW1 for 3 minutes, operate in the eleventh transfer mode M11 for 3 minutes, operate in the second switch transfer mode SW2 for 3 minutes, and then operate in the third switch transfer mode SW3 for 3 minutes. In addition, in the tenth SMS transfer mode, the element transfer device 100 may perform one cycle of operating in the seventh transfer mode M7, the first switch transfer mode SW1, the eleventh transfer mode M11, the second switch transfer mode SW2, and the third switch transfer mode SW3.

The eleventh SMS transfer mode is a transfer mode in which the element transfer device 100 sequentially operates in the seventh transfer mode M7, the first switch transfer mode SW1, the eleventh transfer mode M11, the second switch transfer mode SW2, and a fourth switch transfer mode SW4. In the eleventh SMS transfer mode, the element transfer device 100 may operate in the seventh transfer mode M7 for 3 minutes, operate in the first switch transfer mode SW1 for 3 minutes, operate in the eleventh transfer mode M11 for 3 minutes, operate in the second switch transfer mode SW2 for 3 minutes, and then operate in the fourth switch transfer mode SW4 for 3 minutes. In addition, in the eleventh SMS transfer mode, the element transfer device 100 may perform one cycle of operating in the seventh transfer mode M7, the first switch transfer mode SW1, the eleventh transfer mode M11, the second switch transfer mode SW2, and the fourth switch transfer mode SW4.

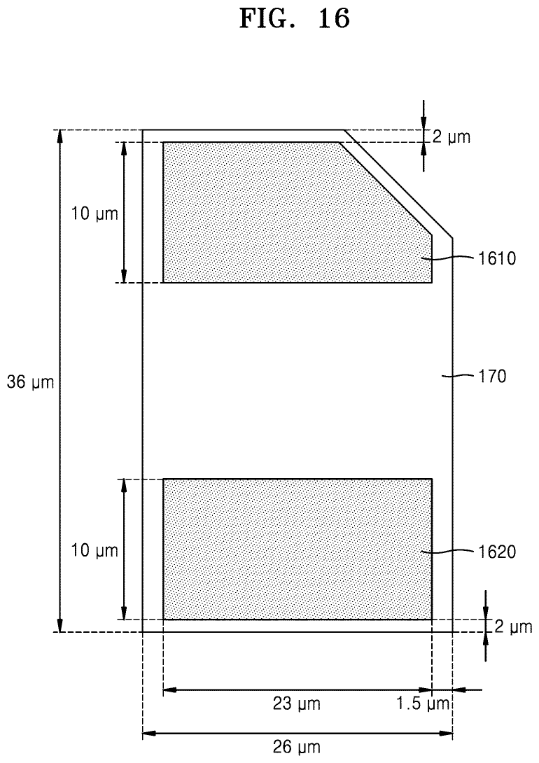

FIG. 16 is a diagram illustrating a structure of a microelement according to an embodiment.

According to an embodiment, a microelement 170 may have a pentagonal shape obtained by removing one vertex from a rectangular structure. The microelement 170 may have an asymmetric structure in which the top, bottom, left, and right sides are distinguishable. The microelement 170 may include a first electrode 1610 and a second electrode 1620. One of the first electrode 1610 and the second electrode 1620 may correspond to a cathode electrode, and the other may correspond to an anode electrode. Positions of the electrodes may be configured in the same manner as those of a typical lateral chip or flip chip. Lateral chips and flip chips have structures in which electrodes are arranged on a single plane, and the microelement 170 may have an electrode structure similar to that of a lateral chip or a flip chip.

The size of the microelements 170 shown in FIG. 16 is a size according to an example of the disclosure. According to an embodiment, the microelement 170 may have a height of 36 μm and a width of 26 μm. The first electrode 1610 may have a height of 10 μm and a width of 23 μm. In addition, the second electrode 1620 may have a height of 10 μm and a width of 23 μm. The first electrode 1610 and the second electrode 1620 may be formed about 1.5 μm to about 2 μm away from an edge of the microelement 170. The microelement 170 may have a thickness of 6 μm or less. The microelement 170 may correspond to an LED chip. The microelement 170 may be manufactured by forming a GaN epitaxial layer on a sapphire substrate and removing one vertex by using a laser-lift-off (LLO) method.

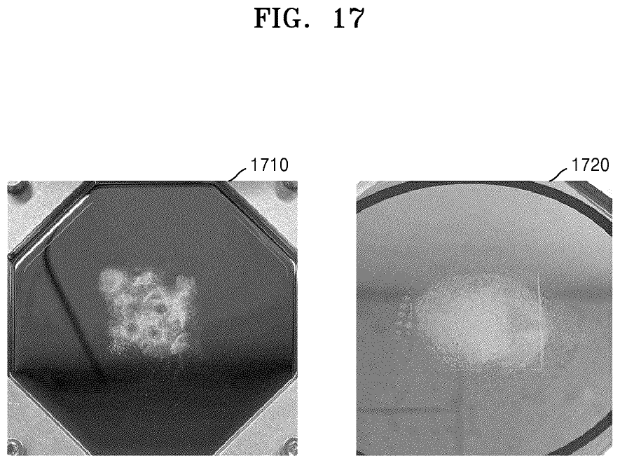

FIG. 17 is a diagram illustrating a result of a dispersion operation according to an embodiment and a result of a dispersion operation according to a comparative example.

FIG. 17 shows results of experiments conducted using the microelements 170 in the form of circular chips. An image 1710 shows an experimental result according to a comparative example, and an image 1720 shows a result of a dispersion operation according to an embodiment. The image 1710 shows a dispersion state after introducing the microelements 170 into a fluid within the container 120 by using a pipette. The image 1720 shows a state after performing the dispersion operation by using the floating mask 150 and then removing the floating mask 150.

As shown in FIG. 17, when the microelements 170 were introduced using the pipette, the microelements 170 were observed to be unevenly distributed and clustered together. In contrast, when the microelements 170 were dispersed using the floating mask 150 according to an embodiment, the microelements 170 were observed to be distributed relatively uniformly.

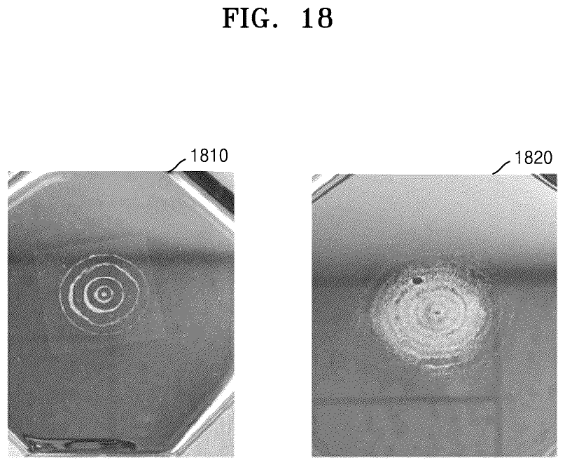

FIG. 18 is a diagram illustrating a result of a dispersion operation according to an embodiment and a result of a dispersion operation according to a comparative example.

FIG. 18 shows results of transferring the microelements 170 onto the substrate 160 by performing a certain transfer mode after the dispersion results shown in FIG. 17. An image 1810 shows a result of a transfer operation according to a comparative example, and an image 1820 shows a result of a transfer operation according to an embodiment. The experimental results of FIG. 18 are results of applying, to the container 120 according to the comparative example and the container 120 according to an embodiment, a vibration of 66 Hz for 5 minutes from a pair of vibration sources on a first short axis and a vibration of about 67 Hz to about 69 Hz for 5 minutes from a pair of vibration sources on a second short axis.

According to the comparative example, as shown in the image 1810, the microelements 170 were not uniformly arranged on the substrate 160 and were clustered together in the form of concentric circles. The microelements 170 were clustered along nodal lines of vibrations output from the plurality of vibration sources 130 and thus were not uniformly arranged on the substrate 160. In contrast, according to an embodiment, as shown in the image 1820, even after performing the transfer operation, the microelements 170 were observed to be uniformly distributed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An element transfer device comprising:
a polygonal container accommodating a substrate comprising a plurality of element holes;
a plurality of vibration sources configured to generate vibrations and output the vibrations to a fluid within the container;
a floating mask arranged on the substrate and comprising a plurality of mask holes;
a processor configured to control an output of each of the plurality of vibration sources,
wherein the container accommodates the floating mask, the fluid, and microelements distributed in the fluid, and
the processor is further configured to perform:
a dispersion operation of controlling, in a state in which the floating mask is arranged on the substrate, the microelements to be dispersed in the fluid on the substrate through the plurality of mask holes in the floating mask by outputting vibration from at least one of the plurality of vibration sources; and
a transfer operation of transferring, in a state in which the floating mask is removed from the container in which the substrate is arranged, the microelements into the plurality of element holes in the substrate by outputting vibration from at least one of the plurality of vibration sources.

2. The element transfer device of claim 1, further comprising a spacer attached to a bottom portion of the floating mask and preventing contact between the floating mask and the substrate, wherein the floating mask is arranged on the substrate such that the spacer is in contact with the substrate.

3. The element transfer device of claim 1, wherein the plurality of vibration sources comprise: at least one vibration source of a first group, which is arranged on a circumference of a first circle having a radius of a first distance from a center point of the container; and at least one vibration source of a second group, which is arranged on a circumference of a second circle having a radius of a second distance greater than the first distance, the second circle being concentric with the first circle.

4. The element transfer device of claim 3, wherein the at least one vibration source of the first group is disposed on at least one short axis passing through the center point, and comprises at least one pair of vibration sources of the first group that face each other with respect to the center point, and
the at least one vibration source of the second group is disposed on at least one long axis passing through the center point, and comprises at least one pair of vibration sources of the second group that face each other with respect to the center point.

5. The element transfer device of claim 4, wherein the container has an octagonal shape, and
each of the at least one short axis and the at least one long axis corresponds to each corner of the octagonal container.

6. The element transfer device of claim 1, wherein the processor is further configured to, in the dispersion operation, control the floating mask to rotate by outputting a vibration wave from one of the plurality of vibration sources.

7. The element transfer device of claim 4, wherein the processor is further configured to, in the dispersion operation, reciprocally rotate the floating mask by outputting a vibration of a first frequency from a pair of vibration sources arranged on a first short axis among the at least one vibration source of the first group, and outputting a vibration of a second frequency different from the first frequency from a pair of vibration sources arranged on a second short axis among the at least one vibration source of the first group.

8. The element transfer device of claim 7, wherein the processor is further configured to control a direction of the reciprocating rotation by adjusting a frequency and amplitude of the vibration output from the pair of vibration sources of the first group on the first short axis, and adjusting a frequency and amplitude of the vibration output from the pair of vibration sources of the first group on the second short axis.

9. The element transfer device of claim 1, wherein the floating mask comprises at least one of aluminum, stainless steel, Invar, or a high-rigidity organic material.

10. The element transfer device of claim 1, wherein the floating mask has a thickness of about 0.1 mm to about 1 mm.

11. The element transfer device of claim 1, wherein the plurality of mask holes in the floating mask have diameters of about 0.1 mm to about 0.3 mm and are arranged in a two-dimensional array form with a pitch of about 0.1 mm to about 0.3 mm.

12. The element transfer device of claim 1, wherein the substrate corresponds to a display panel included in a display module,
the microelements are light-emitting elements transferred onto the display panel,
a pattern of the plurality of mask holes in the floating mask corresponds to a resolution of the display module, and
sizes of the plurality of mask holes are greater than sizes of the microelements by more than 0% and less than or equal to about 15%.

13. The element transfer device of claim 1, wherein the processor is further configured to:
obtain a first image of the substrate within the container in a state in which the floating mask is removed; and
in the transfer operation, control, based on the first image, the plurality of vibration sources by using at least one of a plurality of transfer modes in which a predefined output frequency is output via at least one of the plurality of vibration sources.

14. The element transfer device of claim 13, wherein the processor is further configured to control the plurality of vibration sources to operate sequentially in two or more transfer modes among the plurality of transfer modes.

15. The element transfer device of claim 13, wherein the processor is further configured to:
determine, based on the first image, a transfer state of the microelements being transferred into the plurality of element holes in the substrate and positions of residual microelements that are not transferred onto the substrate; and
control, based on the transfer state and the positions of the residual microelements, the plurality of vibration sources to operate in at least one transfer mode among the plurality of transfer modes.

16. The element transfer device of claim 1, wherein the vibrations generated by the plurality of vibration sources have frequencies of about 20 Hz to about 100 MHz.

17. The element transfer device of claim 1, further comprising a plurality of connection plates respectively connecting the container and each of the plurality of vibration sources together.

18. The element transfer device of claim 1, further comprising a camera configured to capture an image of the substrate within the container,
wherein the processor is further configured to determine, based on the image of the substrate captured by the camera, a transfer state of the microelements being transferred into the plurality of element holes in the substrate, and
determine a transfer mode of the plurality of vibration sources based on the determined transfer state.

19. The element transfer device of claim 1, wherein the fluid comprises at least one of water, ethanol, acetone, isopropyl alcohol (IPA), ethylene glycol, dimethyl sulfoxide, glycerol, tetrahydrofuran, silicone oil, or nucleic acid.

20. A method for controlling an element transfer device, the method comprising:
a dispersion operation of controlling, in a state in which a substrate comprising a plurality of element holes is arranged within a polygonal container storing a fluid and a floating mask is arranged on the substrate, microelements to be dispersed in the fluid on the substrate through a plurality of mask holes in the floating mask by outputting vibration from at least one of a plurality of vibration sources; and
a transfer operation of transferring, in a state in which the floating mask is removed from the container in which the substrate is arranged, the microelements into the plurality of element holes in the substrate by outputting vibration from at least one of the plurality of vibration sources.
